(19) United States
(12) Patent Application Publication
(10) Pub. No.: US 2005/0201100 A1
(43) Pub. Date: Sep. 15, 2005

(54) Led lighting assembly

(76) Inventors: William James Cassarly, Mason, OH (US); Robert D. Galli, Las Vegas, NV (US)

Correspondence Address: BARLOW, JOSEPHS & HOLMES, LTD., 101 DYER STREET, 5TH FLOOR, PROVIDENCE, RI, 02903, US

(21) Appl. No.: 11/109,117

(22) Filed: Apr. 19, 2005

Related U.S. Application Data
(63) Continuation-in-part of application No. 10/731,392, filed on Dec. 9, 2003.
Application No. 10/731,392 is a continuation-in-part of application No. 10/658,613, filed on Sep. 8, 2003, now Pat. No. 6,819,505.

(51) Int. Cl. H01L 27/00

(52) U.S. Cl. 362/317

(57) ABSTRACT

The present invention provides an optical lens for coupling the light output from a high intensity light source, such as an LED, with a light conduit. The optical lens captures, homogenizes and transmits substantially all of the light emitted the light source to a point of convergence that is centrally located on the output face of the optical lens. The present invention transmits upwards of 85% of the light emitted by the light source and produces a uniformly illuminated circular focal point that is easily discharged into the terminal end of an optical conduit such as an optical fiber of light pipe. Optionally the lens may be formed to include structure that serves to receive and retain the terminal end of the optical conduit.

### CROSS-REFERENCE TO RELATED APPLICATIONS

This application is related to and is a continuation-in-part of U.S. patent application Ser. No. 10/731,392, filed Dec. 9, 2003, which is a continuation-in-part of U.S. patent application Ser. No. 10/658,613, filed Sep. 8, 2003, now U.S. Pat. No. 6,819,505.

### BACKGROUND OF THE INVENTION

The present invention relates to a new assembly for coupling a high intensity LED lamp with a light conduit. More specifically, this invention relates to an assembly for coupling a high intensity LED lamp to a light conduit using an high efficiency optical control element.

Currently, several manufacturers are producing high brightness light emitting diode (LED) packages in a variety of forms. These high brightness packages differ from conventional LED lamps in that they use emitter chips of much greater size, which accordingly have much higher power consumption requirements. In general, these packages were originally produced for use as direct substitutes for standard LED lamps. However, due to their unique shape, size and power consumption requirements they present manufacturing difficulties that were originally unanticipated by the LED manufacturers. One example of a high brightness LED of this type is the Luxeon™ Emitter Assembly LED (Luxeon is a trademark of Lumileds Lighting, LLC). The Luxeon LED uses an emitter chip that is four times greater in size than the emitter chip used in standard LED lamps. While this LED has the desirable characteristic of producing a much greater light output than the standard LED, it also generates a great deal more heat than the standard LED. If this heat is not effectively dissipated, it may cause damage to the emitter chip and the circuitry required to drive the LED.

Often, to overcome the buildup of heat within the LED, a manufacturer will incorporate a heat dissipation pathway within the LED package itself. The Luxeon LED, for example, incorporates a metallic contact pad into the back of the LED package to transfer the heat out through the back of the LED. In practice, it is desirable that this contact pad in the LED package be placed into contact with further heat dissipation surfaces to effectively cool the LED package. In the prior art attempts to incorporate these packages into further assemblies, the manufacturers that used the Luxeon LED have attempted to incorporate them onto circuit boards that include heat transfer plates adjacent to the LED mounting location to maintain the cooling transfer pathway from the LED. While these assemblies are effective in properly cooling the LED package, they are generally bulky and difficult to incorporate into miniature flashlight devices. Further, since the circuit boards that have these heat transfer plates include a great deal of heat sink material, making effective solder connections to the boards is difficult without applying a large amount of heat. The Luxeon LED has also been directly mounted into plastic flashlights with no additional heat sinking. Ultimately however, these assemblies malfunction due to overheating of the emitter chip, since the heat generated cannot be dissipated.

Further, because of the large form factor of the emitter chip in these assemblies they tend to emit light over a wide output angle. It is well known in the art that various combinations of lenses and reflectors can be used in conjunction to capture and redirect the wide angle output portion of the radiation distribution of the light emitted. For example, many flashlights available on the market today include a reflector cup around a light source to capture the radiation that is directed from the sides of the light source and redirect it in forward direction, and a convex lens that captures and focuses both the direct output from the light source and the redirected light from the reflector cup. While this is the common approach used in the manufacture of compact lighting devices such as flashlights, this method includes several inherent drawbacks. First, while this arrangement can capture much of the output radiation from the light source, the captured output is only slightly collimated. Light that exits from the light source directly without contacting the reflector surface still has a fairly a wide output angle that allows this direct light output to remain divergent in the far field of the lighting device. Therefore, to collimate this light in an acceptable manner and provide a focused beam, a strong refractive lens must be used. The drawback is that when a lens of this type is used, the image of the light source is directly transferred into the far field of the beam. Second, the light output is not well homogenized using an arrangement of this type. While providing facets on the interior of the reflector surface assists in smearing edges of the image, generally a perfect image of the actual light-generating source is transferred directly into the far field of the beam. In the case of an incandescent, halogen or xenon light source this is an image of a spirally wound filament and in the case of light emitting diodes (LEDs) it is a square image of the emitter die itself. Often this direct transfer of the light source image creates a rough appearance to the beam that is unattractive and distracting for the user of the light. Third, most of these configurations are inefficient and transfer only a small portion of the radiational output into the on axis output beam of the lighting device. Finally, these devices require several separate components to be assembled into mated relation. In this manner, these devices create additional manufacturing and assembly steps that increase the overall cost of the device and increase the chance of defects.

Several prior art catadioptric lenses combine the collector function with a refractive lens in a single device that captures and redirects the radiational output from a light source. U.S. Pat. No. 2,215,900, issued to Bitner, discloses a lens with a recess in the rear thereof into which the light source is placed. The angled sides of the lens act as reflective surfaces to capture light from the side of the light source and direct it in a forward manner using TIR principals. The central portion of the lens is simply a convex element to capture the on axis illumination of the light source and re-image it into the far field. Further, U.S. Pat. No. 2,254,961, issued to Harris, discloses a similar arrangement as Bitner but discloses reflective metallic walls around the sides of the light source to capture lateral radiation. In both of these devices, the on-axis image of the light source is simply an image of the light generating element itself and the lateral radiation is transferred as a circle around the central image. In other words, there is little homogenizing of the light as it passes through the optical assembly. Further, since these devices anticipate the use of a point source type light element, such as is found in filament type lamps, a curvature is provided in the front of the cavity to capture the divergent on axis output emanating from a single point to create a collimated and parallel output. Therefore, a relatively shallow optical curvature is indicated in this application.

Another prior art catadioptric lens is shown in U.S. Pat. No. 5,757,557. This type collimator is referred to as the “flat top tulip” collimator. In its preferred embodiment, it is a solid plastic piece with an indentation at the entrance aperture. The wall of the indentation is a section of a circular cone and the indentation terminates in a shallow convex lens shape. A light source (in an appropriate package) injects its light into the entrance aperture indentation, and that light follows one of two general paths. On one path, it impinges on the inner (conic) wall of the solid collimator where it is refracted to the outer wall and subsequently reflected (typically by TIR) to the exit aperture. On the other path, it impinges on the refractive lens structure, and is then refracted towards the exit aperture. This is illustrated schematically in FIG. 1A. As stated above, the collimator 2 is designed to produce perfectly collimated light 7 from an ideal point source 4 placed at the focal point of the lens 2. A clear limitation is that when it is used with a real extended source 6 of appreciable surface area (such as an LED chip) as seen in FIG. 1B, the collimation is incomplete and the output is directed into a diverging conic beam that includes a clear image of the chip as a central high intensity region 8 and a secondary halo region 9.

When a high intensity light source if manufactured using the prior art structures disclosed above, the device quickly becomes quite large in order to allow for all of the required tolerances and to accommodate the desired functionality. There is therefore a need for a compact assembly that provides for coupling a high intensity LED package with a light conduit that provides high collection and transfer efficiency. There is a further need for a compact lighting assembly that includes a high level of optical control through the use of a catadioptric lens assembly that collimates the light output from a light source while also homogenizing the output to produce a smoothly illuminated and uniform beam image that can be transferred into a light conduit without requiring additional coupling structures.

### BRIEF SUMMARY OF THE INVENTION

In this regard, the present invention provides an assembly that incorporates a high intensity LED package, such as the Luxeon Emitter Assembly described above, into an integral housing for further incorporation into other useful lighting devices. The present invention can be incorporated into a variety of lighting assemblies including but not limited to flashlights, specialty architectural grade lighting fixtures and vehicle lighting. The present invention primarily includes two housing components, namely an inner mounting die, and an outer enclosure. The inner mounting die is formed from a highly thermally conductive material. While the preferred material is brass, other materials such as thermally conductive polymers or other metals may be used to achieve the same result. The inner mounting die is cylindrically shaped and has a recess in the top end. The recess is formed to frictionally receive the mounting base of a high intensity LED assembly. A longitudinal groove is cut into the side of the inner mounting die that may receive an insulator strip or a strip of printed circuitry, including various control circuitry thereon. Therefore, the inner mounting die provides both electrical connectivity to one contact of the LED package and also serves as a heat sink for the LED. The contact pad at the back of the LED package is in direct thermal communication with the inner surface of the recess at the top of the inner mounting die thus providing a highly conductive thermal path for dissipating the heat away from the LED package.

The outer enclosure of the present invention is preferably formed from the same material as the inner mounting die. In the preferred embodiment, this is brass but may be thermally conductive polymer or other metallic materials. The outer enclosure slides over the inner mounting die and has a circular opening in the top end that receives the clear optical portion of the Luxeon LED package therethrough. The outer enclosure serves to further transfer heat from the inner mounting die and the LED package, as it is also highly thermally conductive and in thermal communication with both the inner mounting die and the LED package. The outer enclosure also covers the groove in the side of the inner mounting die protecting the insulator strip and circuitry mounted thereon from damage.

Additionally, the present invention includes an optical element coupled with the mounting assembly that is well suited for use with LED light sources, which do not approximate a point source for luminous flux output. The optical element includes a recessed area into which the light source is placed. The front of the recess further includes an inner lens area for gathering and focusing the portion of the beam output that is emitted by the light source along the optical axis of the optical attachment. Further, the optical attachment includes an outer reflector area for the portion of the source output that is directed laterally or at large angles relative to the optical axis of the device. The reflector portion and the inner lens direct the light output through a transition region where the light is focused and homogenized. The convex optics at the front of the transition region images this focused and homogenized light into the far field of the device. Assembled in this manner, the present invention can be incorporated into any type of lighting device.

Finally, the present invention in another embodiment provides for an optical assembly that is well suited for use in conjunction with an LED package wherein a high percentage of the light output from the LED is collected and directed forward in a manner that allows the light to be coupled into a light conduit.

Accordingly, one of the objects of the present invention is the provision of an optical assembly for coupling a high intensity LED with a light conduit. Another object of the present invention is the provision of an assembly for coupling a high intensity LED with a light conduit that is highly efficient and serves to transfer a high percentage of the LED light output into the light conduit. Yet a further object of the present invention is the provision of an assembly for packaging a high intensity LED that includes integral means for coupling the LED with a light conduit using a one piece optical assembly that captures both the on axis and lateral luminous output and collimates the output to create a homogenous beam image at the input end of the light conduit. A further object of the present invention is the provision of an assembly for packaging a high intensity LED that includes an integrated optical assembly that creates a homogenous and focused beam image at the output face thereof that is further coupled into a light conduit.

Other objects, features and advantages of the invention shall become apparent as the description thereof proceeds when considered in connection with the accompanying illustrative drawings.

### BRIEF DESCRIPTION OF THE DRAWINGS

In the drawings which illustrate the best mode presently contemplated for carrying out the present invention:

FIG. 1A is a cross-sectional view of a prior art catadioptric lens showing ray traces from a theoretical point source;

FIG. 1B is a cross-sectional view of a prior art catadioptric lens showing ray traces from a high intensity LED source;

FIG. 2 is a perspective view of the LED lighting assembly of the present invention;

FIG. 3 is a perspective view of the LED and heat sink sub-assembly portion of the present invention;

FIG. 4 is a front view thereof;

FIG. 5 is rear view thereof;

FIG. 6 is an exploded perspective thereof;

FIG. 7 is a cross-sectional view thereof as taken along line 7-7 of FIG. 3;

FIG. 8 is a schematic diagram generally illustrating the operational circuitry of present invention as incorporated into a complete lighting assembly.

FIG. 9 is an exploded perspective view of a first alternate embodiment of the present invention;

FIG. 10 is a cross-sectional view thereof as taken along line 10-10 of FIG. 9;

FIG. 11 is an exploded perspective view of a second alternate embodiment of the present invention;

FIG. 12 is a cross-sectional view thereof as taken along line 12-12 of FIG. 11;

FIG. 13 is an exploded perspective view of a third alternate embodiment of the present invention;

FIG. 14 is a cross-sectional view thereof as taken along line 14-14 of FIG. 13;

FIG. 15 is a cross-sectional view of the optical lens of the present invention;

FIG. 16 is a cross-sectional view thereof in conjunction with a light source and ray tracing;

FIG. 17a is a plan view showing the light beam pattern of a prior art lighting assembly;

FIG. 17b is a plan view showing the light beam pattern of the present invention;

FIG. 18a is a side view of the optical lens of the present invention;

FIG. 18b is a side view of a first alternate embodiment thereof;

FIG. 18c is a side view of a second alternate embodiment thereof;

FIG. 19 is a side view thereof shown with an aperture stop;

FIG. 20a is a front perspective view of the front surface of the present invention with honeycomb facets shown thereon;

FIG. 20b is a front perspective view of the front surface of the present invention with circular facets shown thereon;

FIG. 21 is a side view of a third alternate embodiment coupled with a light conduit;

FIG. 21A is a side view of the third alternate embodiment with a shim shown for positioning the LED relative to the optical lens;

FIG. 22 is a side view showing a light conduit positioned in spaced relation to the optical lens of the present invention;

FIG. 23 is a side view of a fourth alternate embodiment coupled with a light conduit; and

FIG. 24 is a side view of a fifth alternate embodiment coupled with a light conduit.

### DETAILED DESCRIPTION OF THE INVENTION

Referring now to the drawings, the light emitting diode (LED) lighting assembly of the present invention is illustrated and generally indicated at 1. The lighting assembly 1 generally includes an LED and heat sink sub-assembly 10 and an optical assembly 60 that are contained and maintained in spaced relation within an outer housing 62. As will hereinafter be more fully described, the present invention illustrates an LED lighting assembly 1 for further incorporation into a lighting device. For the purposes of providing a preferred embodiment of the present invention, the device 1 will be shown incorporated into a generic housing 62 with two power supply leads 64, 66 extending therefrom, however, the present invention also may be incorporated into any other lighting device such as architectural specialty lighting, vehicle lighting, portable lighting or flashlights. In general, the present invention provides a means for packaging a high intensity LED lamp that includes integral heat sink capacity, electrical connectivity and an optical assembly for controlling the light output from the LED. The present invention therefore provides a convenient and economical assembly 1 for incorporating a high intensity LED into a lighting assembly that has not been previously available in the prior art.

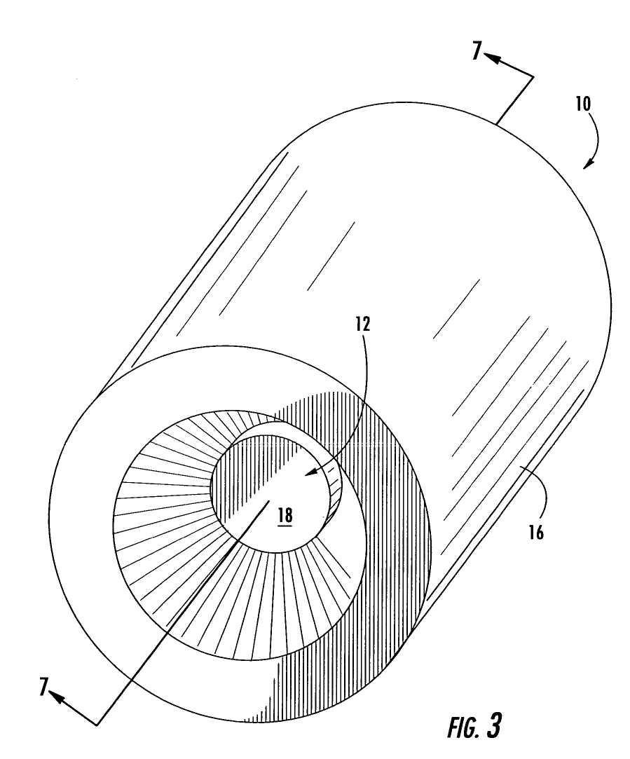

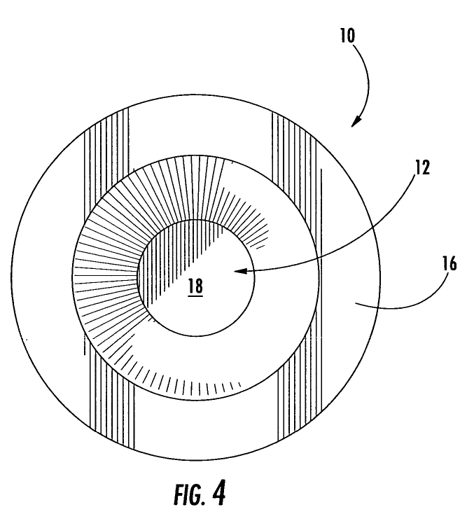

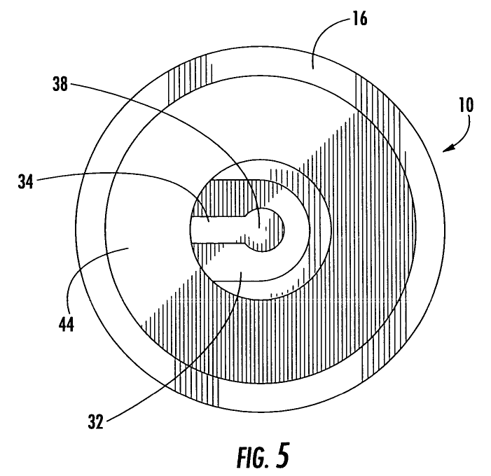

Turning to FIG. 2, the LED, heat sink and optical assembly 1 can be seen in a fully assembled state and includes one embodiment of an LED and heat sink sub-assembly 10. The main parts of the sub-assembly 10 can be seen to include a high intensity LED lamp 12 and an inner mounting die 14. In an alternate embodiment, as is shown in FIGS. 3-7, the sub-assembly may also include outer enclosure 16. In FIGS. 2 and 3, the lens 18 of the LED 12 can be seen extending through an opening in the front wall of the outer enclosure 16. Further, in FIG. 4 a rear view of the sub-assembly 10 of the present invention can be seen with a flexible contact strip 32 shown extending over the bottom of the interior die 14.

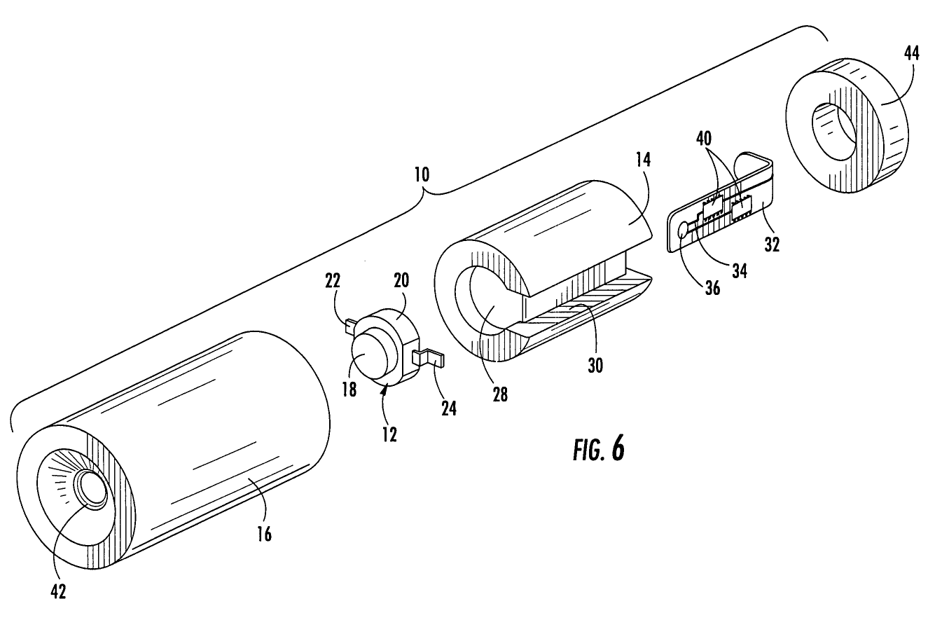

Turning now to FIGS. 6 and 7, an exploded perspective view and a cross sectional view of the sub-assembly 10 of the present invention can be seen. The sub-assembly 10 of the present invention is specifically configured to incorporate a high intensity LED lamp 12 into a package that can be then used in a lighting assembly. The high intensity LED lamp 12 is shown here as a Luxeon Emitter assembly. However, it should be understood that the mounting arrangement described is equally applicable to other similarly packaged high intensity LED's. The LED 12 has a mounting base 20 and a clear optical lens 18 that encloses the LED 12 emitter chip (not shown). The LED 12 also includes two contact leads 22, 24 that extend from the sides of the mounting base 20, to which power is connected to energize the emitter chip. Further, the LED lamp 12 includes a heat transfer plate 26 positioned on the back of the mounting base 20. Since the emitter chip in this type of high intensity LED lamp 12 is four times the area of a standard emitter chip, a great deal more energy is consumed and a great deal more heat is generated. The heat transfer plate 26 is provided to transfer waste heat out of the LED lamp 12 to prevent malfunction or destruction of the chip. In this regard, the manufacturer has provided the heat transfer plate 26 for the specific purpose of engagement with a heat sink. However, all of the recommended heat sink configurations are directed to a planar circuit board mount with a heat spreader or a conventional finned heat sink. Neither of these arrangements is suitable for small package integration or a typical compact lighting head construction.

In contrast, the mounting die 14 used in the present invention is configured to receive the LED lamp 12 and further provide both electrical and thermal conductivity to and from the LED lamp 12. The mounting die 14 is fashioned from a thermally conductive and electrically conductive material. In the preferred embodiment as can be seen in FIG. 2, the mounting die 14 is fashioned from aluminum, however, the die 14 could also be fabricated from other metals such as brass or stainless steel or from an electrically conductive and thermally conductive polymer composition and still fall within the scope of this disclosure. The mounting die 14 has a recess 28 in one end thereof that is configured to receive the base 20 of the LED lamp 12. While the base 20 and the recess 28 are illustrated as circular, it is to be understood that this recess is intended to receive the housing base regardless of the shape. As can be seen, one of the contact leads 22 extending from the base 20 of the LED lamp 12 must be bent against the surface of the mounting die 14 when the LED lamp 12 is installed into the recess 28. When installed with the first contact lead 22 of the LED 12 retained in this manner, the lead 22 is in firm electrical communication with the mounting die 14. An aperture 31 extends through the mounting die 14 from the recess to the rear of the die 14. When the LED lamp 12 is installed in the mounting die 14, the second contact lead 24 extends into the aperture 31 out of contact with the body of the mounting die 14. The heat transfer plate 26 provided in the rear of the LED lamp 12 base 20 is also in contact with the bottom wall of the recess 28 in the mounting die 14. When the heat transfer plate 26 is in contact with the die 14, the heat transfer plate 26 is also in thermal communication with the die 14 and heat is quickly transferred out of the LED lamp 12 and into the body of the die 14. The die 14 thus provides a great deal of added heat sink capacity to the LED lamp 12.

Further, in FIG. 2, a circuit board 32 is shown installed adjacent the back of the inner mounting die 14. As can be seen, the second contact lead 24 of the LED 12 extends through the aperture 31 in the inner mounting die 14. The contact lead 24 extends through the aperture without contacting the inner mounting die 14. The contact lead 24 extends to the circuit board 32 and is in electrical communication with the circuit board 32. The inner mounting die 14 is in both thermal and electrical communication with the outer housing 62.

Similarly, in an alternate embodiment heat sink sub assembly 10 as can best be seen in FIG. 7, the circuit board strip 32 is placed into the bottom of the channel 30 that extends along the side of the mounting die 14. The circuit board strip 32 allows a conductor to be connected to the second contact lead 24 of the LED lamp 12 and extended through the channel 30 to the rear of the sub-assembly 10 without coming into electrical contact with and short circuiting against the body of the die 14. In the preferred embodiment, the circuit board strip 32 in this embodiment is a flexible printed circuit strip with circuit traces 34 printed on one side thereof. The second contact lead 24 of the LED lamp 12 is soldered to a contact pad 36 that is connected to a circuit trace 34 at one end of the circuit board strip 32. The circuit trace 34 then extends the length of the assembly and terminated in a second contact pad 38 that is centrally located at the rear of the assembly 10. Further, control circuitry 40 may be mounted onto the flexible circuit strip 32 and housed within the channel 30 in the die 14. The control circuitry 40 includes an LED driver circuit as is well known in the art.

With the LED lamp 12 and circuit board strip 32 installed on the mounting die 14, the mounting die 14 is inserted into the outer enclosure 16. The outer enclosure 16 is also fashioned from a thermally conductive and electrically conductive material. In the preferred embodiment the outer enclosure 16 is fashioned from brass, however, the outer enclosure 16 could also be fabricated from other metals such as aluminum or stainless steel or from an electrically conductive and thermally conductive polymer composition and still fall within the scope of this disclosure. The outer enclosure 16 has a cavity that closely matches the outer diameter of the mounting die 14. When the mounting die 14 is received therein, the die 14 and the housing 16 are in thermal and electrical communication with one another, providing a heat transfer pathway to the exterior of the sub-assembly 10. As can also be seen, electrical connections to the sub-assembly 10 can be made by providing connections to the outer enclosure 16 and the contact pad 38 on the circuit trace 34 at the rear of the mounting die 14. Typically this electrical connectivity will be extended utilizing electrical leads 64, 66 to extend the connection means further away from the sub-assembly 10 to facilitate connections being made thereto. The outer enclosure 16 also includes an aperture 42 in the front wall thereof through which the optical lens portion 18 of the LED lamp 12 extends.

Finally, an insulator disk 44 is shown pressed into place in the open end of the outer enclosure 16 behind the mounting die 14. The insulator disk 44 fits tightly into the opening in the outer enclosure 16 and serves to retain the mounting die 14 in place and to further isolate the contact pad 38 at the rear of the mounting die 14 from the outer enclosure 16.

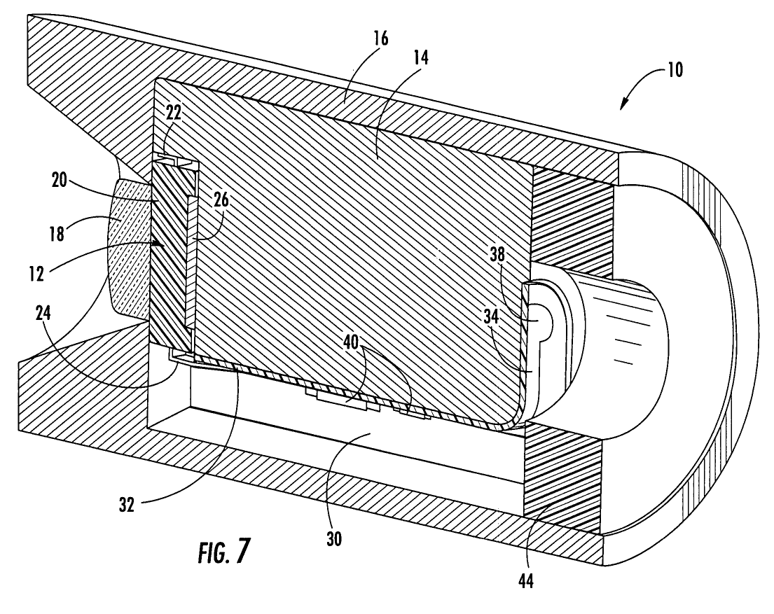

Turning now to FIG. 8, a schematic diagram of a completed circuit showing the LED sub-assembly 10 of the present invention incorporated into functional lighting device is provided. The LED sub-assembly 10 is shown with electrical connections made thereto. A housing 62 is provided and shown in dashed lines. A power source 48 is shown within the housing 62 with one terminal in electrical communication with the outer enclosure 15 of the LED assembly 10 and a second terminal in electrical communication with the circuit trace 38 at the rear of the housing 16 via a switch assembly 50. The switching assembly 50 is provided as a means of selectively energizing the circuit and may be any switching means already known in the art. The housing 62 of the lighting device may also be thermally and electrically conductive to provide additional heat sink capacity and facilitate electrical connection to the outer enclosure 16 of the LED sub-assembly 10.

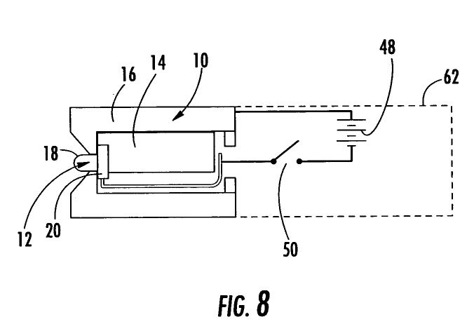

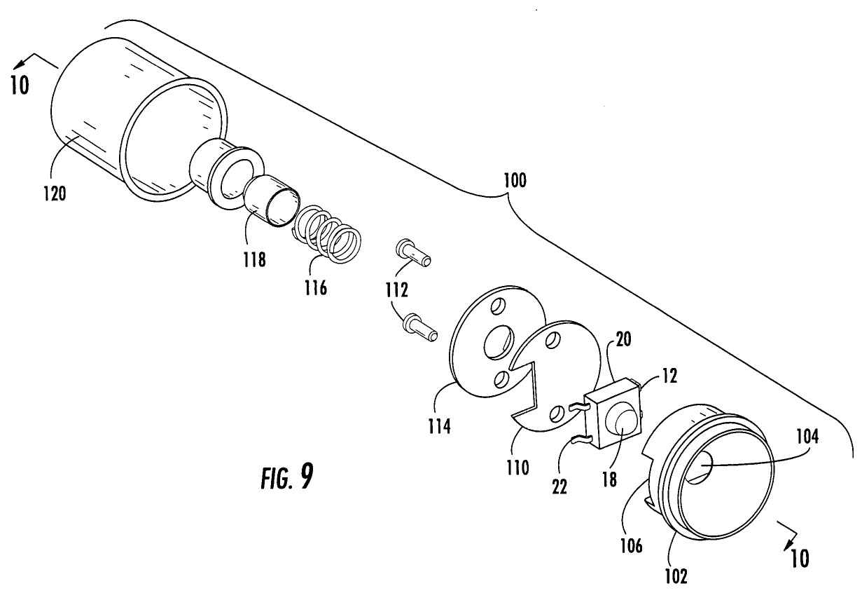

Turning to FIGS. 9 and 10, an alternate embodiment of the LED assembly 100 is shown the outer enclosure is a reflector cup 102 with an opening 104 in the center thereof. The luminescent portion 18 of the LED 12 is received in the opening 104. The reflector cup 102 includes a channel 106 that is cleared in the rear thereof to receive the mounting base 20 of the LED 12 wherein the rear surface of the mounting base 20 is substantially flush with the rear surface 108 of the reflector cup 102 when the LED in 12 is in the installed position. The mounting die is replaced by a heat spreader plate 110. The spreader plate 110 is in thermal communication with both the heat transfer plate on the back of the LED 12 and the rear surface 108 of the reflector cup 102. In this manner when the LED 12 is in operation the waste heat is conducted from the LED 12 through the spreader plate 110 and into the body of the reflector cup 102 for further conduction and dissipation. The spreader plate 110 may be retained in its operative position by screws 112 that thread into the back 108 of the reflector cup 102. Alternatively, a thermally conductive adhesive (not shown) may be used to hold the LED 12, the reflector cup 102 and the spreader plate 110 all in operative relation.

FIGS. 9 and 10 also show the installation of a circuit board 114 installed behind the spreader plate 110. The circuit board 114 is electrically isolated from the spreader plate 110 but has contact pads thereon where the electrical contacts 22 of the LED 12 can be connected. Further a spring 116 may be provided that extends to a plunger 118 that provides an means for bringing power from one battery contact into the circuit board 114. Power from the second contact of the power source may be conducted through the outer housing 120 and directed back to the circuit board. While specific structure is shown to complete the circuit path, it can be appreciated that the present invention is primarily directed to the assembly including merely the reflector cup 102, the LED 12 and the spreader plate 110.

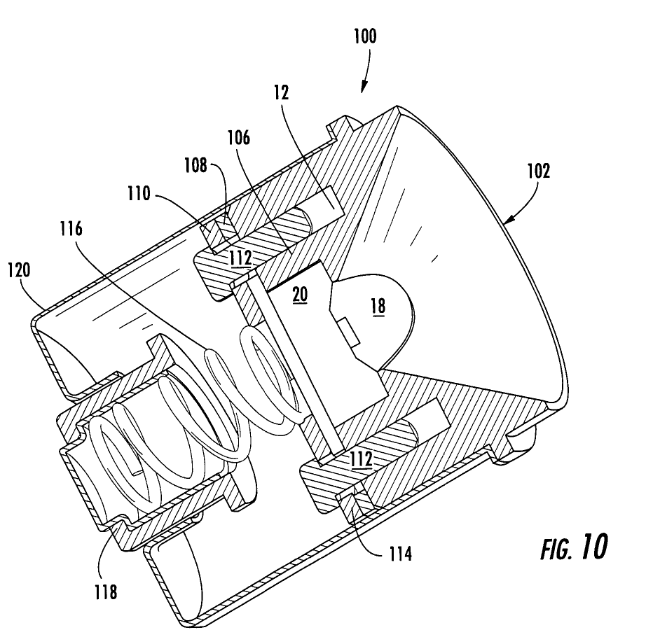

Turning now to FIGS. 11 and 12, a second alternate embodiment is shown where the slot is replaced with a circular hole 202 that receives a Luxeon type LED 12 emitter. Further, a lens 204 is shown for purposes of illustration. In all other respects this particular embodiment is operationally the same as the one described above. It should be note that relief areas 206 are provided in the spreader plate 208 that are configured to correspond to the electrical leads 22 of the LED 12 being used in the assembly. In this manner, the contacts 22 can be connected to the circuit board 210 without contacting the spreader plate 208.

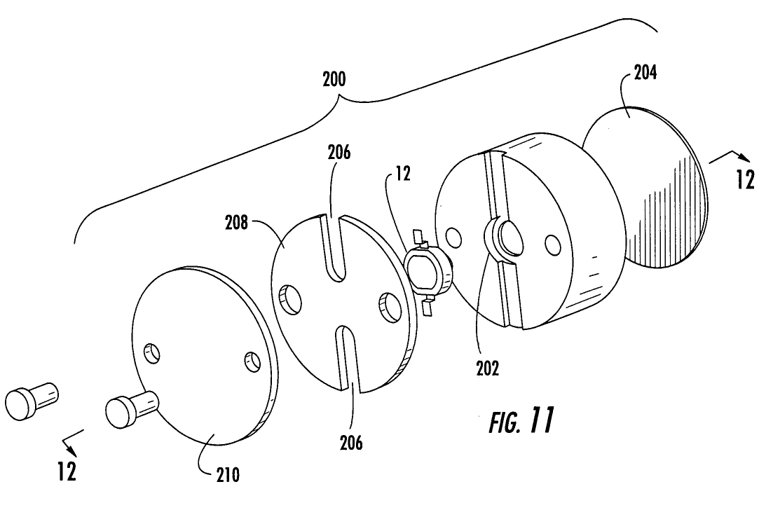

Turning to FIGS. 13 and 14, a third alternate embodiment of the LED assembly 300 is shown. The reflector cup 302 includes both a circular hole 304 and a slot 206 in the rear thereof. The important aspect of the present invention is that the spreader plates 110, 210 or 308 are in flush thermal communication with both the rear surface of the LED 12 and the rear surface of the reflector cups 102, 200 and 302 to allow the heat to be transferred from the LED 12 to the reflector cup 102, 200 and 302.

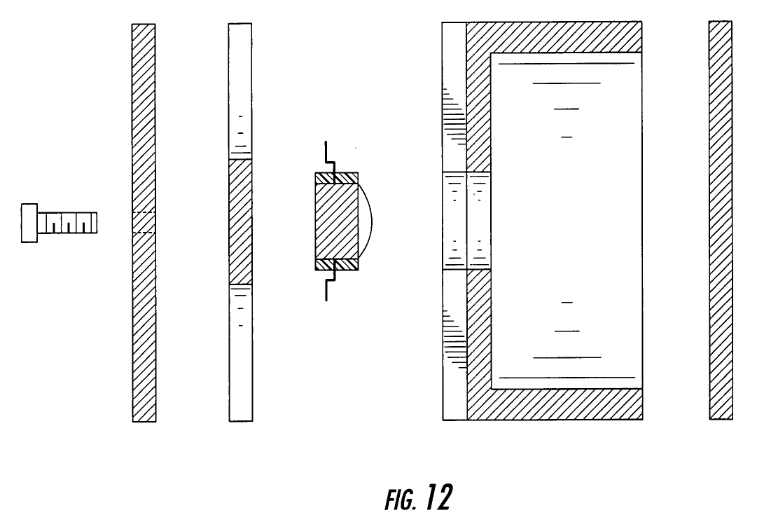

FIG. 15 illustrates the unique lens configuration 60 of the present invention.

The lens 60 can be seen to generally include a total internal reflection (TIR) collector portion 68, a projector lens portion 70 and a transition portion 72 disposed between the collector 68 and the projector 70. As will hereinafter be more fully described, the lens 60 is configured to capture a large amount of the available light from a light source 12, collimate the output and redirect it in a forward fashion to provide a uniformly illuminated circular beam image in the far field of the device. In general the lens 60 of the present invention can be used with any compact light source 12 to provide a highly efficient lens assembly that is convenient and economical for assembly and provides a high quality light output that has not been previously available in the prior art.

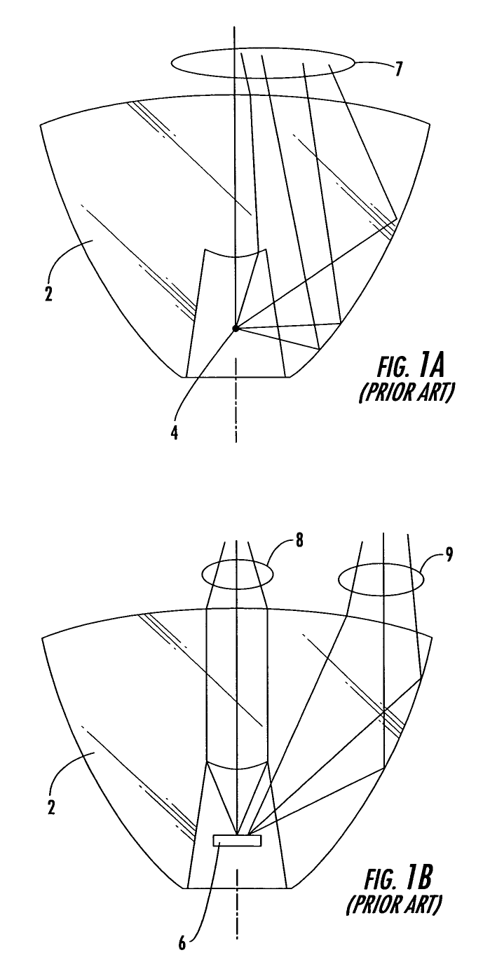

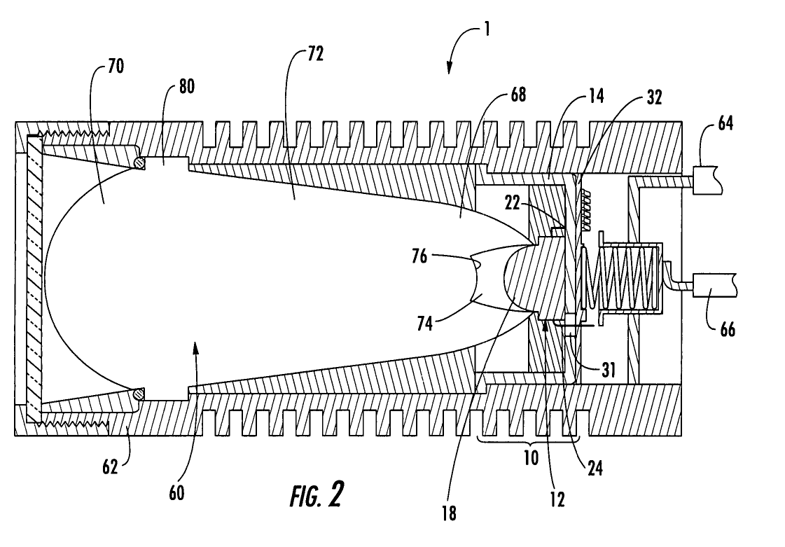

Turning back to FIGS. 1a and 1b, as stated above, the catadioptric lenses 2 of the prior are designed to operate with theoretical point sources 4. By following the ray traces shown in FIG. 1a, it can be seen that a highly focused beam output 7 is generated when the output source is a theoretical point source 4. However, while many high intensity light sources 12 theoretically approximate a point source, in practice, when the output energy is captured and magnified, the light source 12 actually operates as an extended light source 6. As can be best seen in FIG. 1b, a high intensity light emitting diode (LED) 6 is shown in combination with the prior art catadioptric lens 2. The resulting ray traces clearly illustrate that the output includes a central hot spot 8 that is essentially a projected image of the emitter chip 6, resulting from the finite size of the chip 6 and a halo region 9 that results from the emissions from the sides of the chip 6.

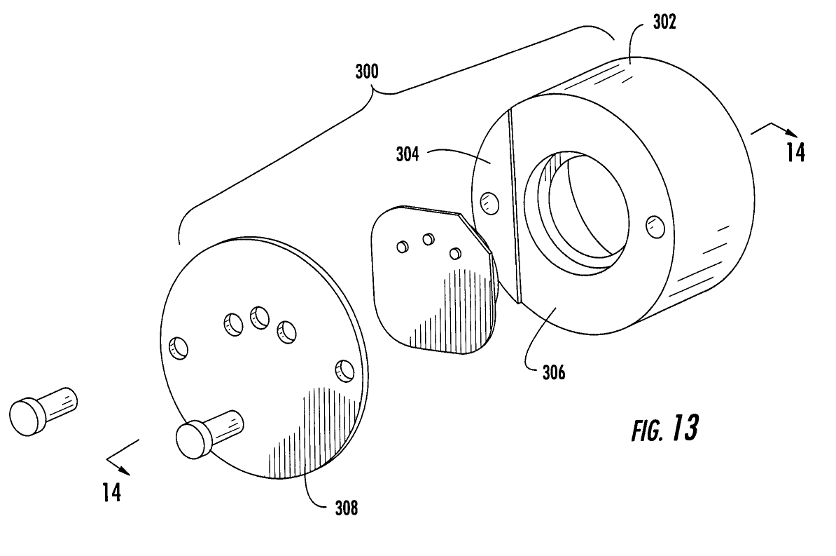

The lens 60 of the present invention is shown in cross-sectional view in FIGS. 15 and 16. The preferred embodiment of the present invention generally includes a TIR collector portion 68, a projector lens portion 70 and a transition section 72 disposed therebetween. The collector portion 68 is configured generally in accordance with the well-known principals of TIR optics. This avoids having to add a reflective coating on the outer surface 73. The collector portion 68 has an outer curved or tapered surface 73 that roughly approximates a truncated conical section. The outer surface 73 may be a straight linear taper, a spherical section, a hyperbolic curve or an ellipsoidal curve. As illustrated in FIG. 15, an ellipsoidal shape has been demonstrated as the most highly efficient shape for use with the preferred high intensity LED light source 12 as will be further described below. The collector 68 includes a recess 74 in the rear thereof that is configured to receive the optical portion 18 of the light source 12. The recess 74 has inner sidewalls 75 and a front wall 76. The inner sidewalls 75 may be straight and parallel or tapered to form a truncated conic section, although some taper is typically required to ensure that the device is moldable. The inner sidewalls 75 act to bend rays toward the collector portion 68 and enhance the collection efficiency of the device. The outer surface 73 and the inner sidewalls 75 are shaped to focus the light from the source within the transition region 72 and near the focal point of the projector lens 70. This generally means that the outer surface 73 will be an asphere, although a true conic shape can be used with only moderate reduction in performance.

The front wall 76 of the recess 74 may be flat or rearwardly convex. In the preferred embodiment, the front wall 76 is formed using an ellipsoidal curve in a rearwardly convex manner. The preferred light source 12 is a high intensity LED device having a mounting base 20, an optical front element 18 and an emitter chip. Generally, LED packages 12 such as described are available in outputs ranging between one and five watts. The drawback is that the output is generally released in a full 1800 hemispherical pattern. The light source 12 in accordance with the present invention is placed into the cavity 74 at the rear of the collector 68 and the collector portion 68 operates in two manners. The first operation is a generally refractive function. Light that exits the light source 12 at a narrow exit angle that is relatively parallel to both the optical axis 77 of the lens 60 and the central axis of the light source 12 is directed into the convex lens 76 at the front wall of the cavity 74. As this on axis 77 light contacts the convex surface 76 of the front wall, it is refracted and bent slightly inwardly towards the optical axis 77 of the lens 60, ultimately being relatively collimated and homogenized as it reaches the focal point 78 of the collector portion 68.

The second operation is primarily reflective. Light that exits the light source 12 at relatively high output angle relative to the optical axis 77 of the lens 60 travels through the lens 60 until it contacts the outer walls 73 of the collector section 68. The outer wall 73 is disposed at an angle relative to the light exiting from the light source 12 as described above to be above the optically critical angle for the optical material from which the lens 60 is constructed. The angle is measured relative to the normal of the surface so that a ray that skims the surface is at 90 degrees. As is well known in the art, light that contacts an optical surface above its critical angle is reflected and light that contacts an optical surface below its critical angle has a transmitted component. The light is redirected in this manner towards the optical axis 77 of the lens 60 assembly and the focal point 78 of the collector portion 68. The curve of the outer wall 73 and the curve of the front surface 76 of the cavity 74 are coordinated to generally direct the collected light toward a single focal point 78. In this manner nearly 85% of the light output from the light source 12 is captured and redirected to a homogenized, focused light bundle that substantially converges at the focal point 78 of the collector portion 68 to produce a highly illuminated, substantially circular, light source distribution.

It is important as is best shown in FIG. 16, that a parallel fan of rays traced from the output face of the lens 60 back towards the source 12 will be distributed across nearly the entire face of the source 12. This manner of using a parallel fan of rays and applying them in a reverse manner through the lens 60 and back to the source 12 is important because the distribution of the rays will indicate whether the optical design of the lens will maximize the on axis intensity of the output beam. The prior art was focused on high collection efficiency and no attempt was made to minimize the fraction of the reverse distributed rays that miss the source 12. The disclosed lens 60 device using a combination of a TIR collector 68 and a projector portion 70 provides this important maximum on-axis intensity advantage, especially when one considers that the angle of inner surface 73 is particularly tailored such that these rearward traced rays that ordinarily just skim the surface of the source 12 are now better focused to cover the entire face of the source 12. Further, this aspect of the lens 60 of the present invention is a novel disclosure that is equally useful with respect to a unitary lens 60 or a lens 60 that is formed in two spaced pieces using a collector portion 68 and a projector portion 70 without a transition section 72.

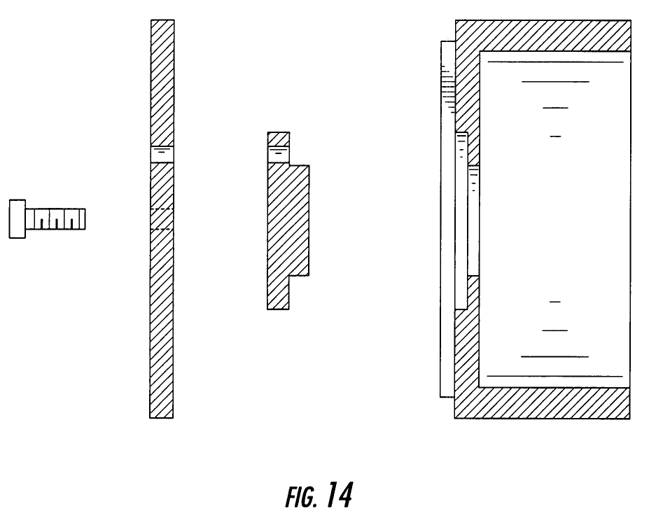

In the lens 60 configuration of the present invention, the placement of the projector portion 70 of the device relative to the collector portion 68 of the device is critical to the proper operation of the lens 60. The projector portion 70 must be placed at a distance from the collector portion 68 that is greater than the focal length 78 of the collector 68. In this manner, the collector 68 can function as described above to focus and homogenize a substantial portion of the light output from the light source 12 into a high intensity, circular, uniformly illuminated near field image. This near field image is produced at a location on the interior of the transition section 72. The near field image is in turn captured by the projector lens 70 and re-imaged or projected into the far field of the device as a uniform circular beam of light as illustrated in FIG. 17b. The transitional portion 72 simply serves as a solid spacer to maintain the ideal relationship between the collector portion 68 and the projector portion 70. This configuration eliminates the prior art approach where two separate devices were employed that had to be spaced apart during the assembly process.

The novelty of the lens 60 is that the entire lens 60 structure is formed in a single unitary lens 60 from either a glass material or an optical grade polymer material such as a polycarbonate. In this manner, a compact device is created that has a high efficiency with respect to the amount of light output that is captured and redirected to the far field of the device and with respect to the assembly of the device. This simple arrangement eliminates the prior art need for combination reflectors, lenses, retention rings and gaskets that were required to accomplish the same function. Further, as can best be seen in FIG. 15 the lens 60 may include an annular ring 80 that lies outside the optically active region of the lens 60. The annular ring 80 forms a mounting surface for installing and retaining the lens 60 in the lighting assembly 1 without affecting the overall operation of the device.

Turning to FIGS. 17a and 17b, images from a prior art conventional LED flashlight using a standard piano convex lens (FIG. 17a) and from a light source in conjunction with the lens of the present invention (FIG. 17b) are shown adjacent to one another for comparison purposes. The image in FIG. 17a can be seen to have poor definition in the transition zone 86 between the illuminated 81 and non-illuminated 82 field areas and an uneven intensity of light can be seen over the entire plane of the illuminated field 81. Areas of high intensity 83 can be witnessed around the perimeter of the illuminated field 81 and in an annular ring 84 near the center of the field 81. In addition, a particularly high intensity area of illumination can be seen in a square box 85 at the center of the field 81 and corresponds to the location of the emitter chip within the LED package. In contrast, FIG. 17b shows an image from the present invention. Note that the illuminated field 87 has a uniform pattern of illumination across the entire plane and the edge 88 between the illuminated 87 and non-illuminated 89 fields is clear and well defined providing high levels of contrast. The relationship between the LED and optical lens components are critical to the operation of the present invention and in providing the results shown in the illumination field in FIG. 17b.

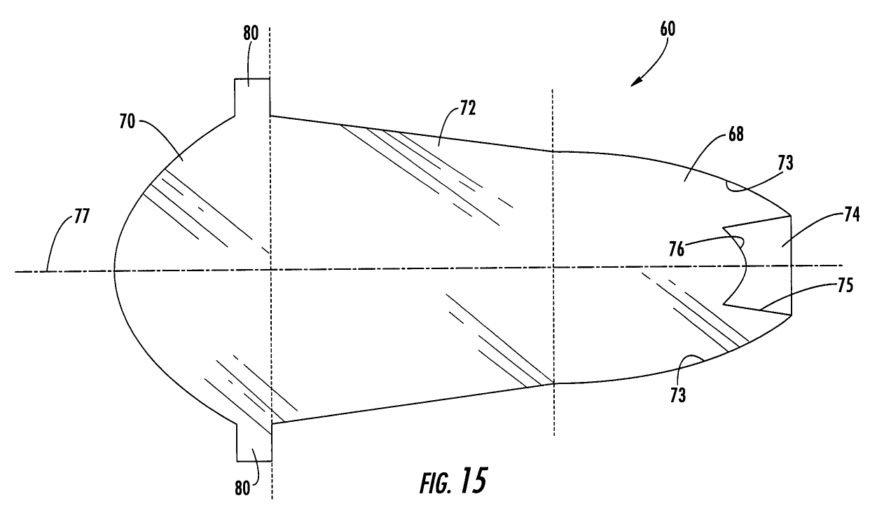

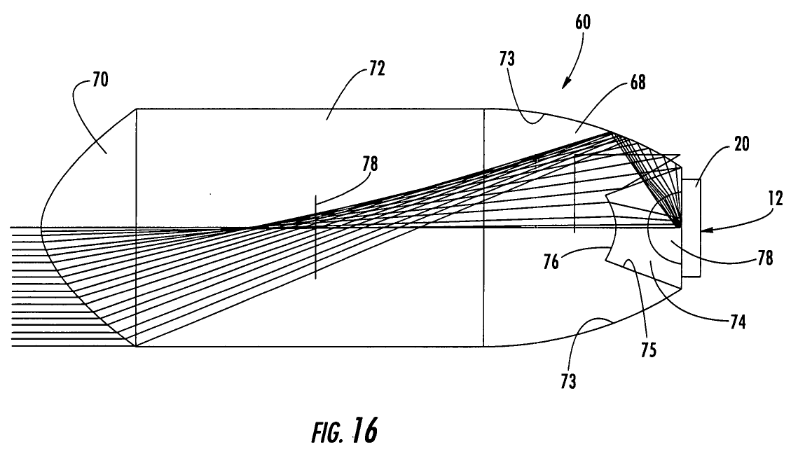

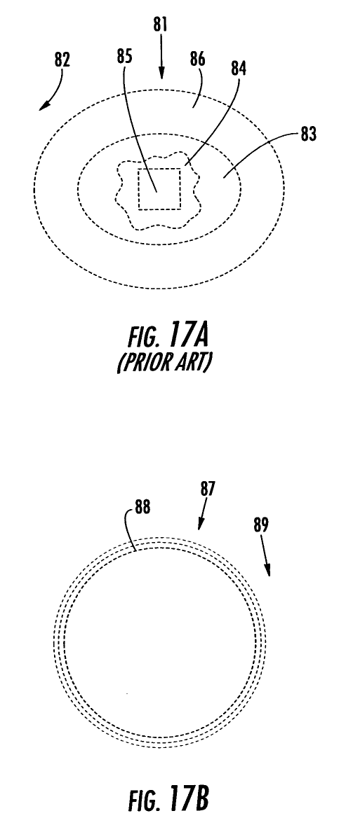

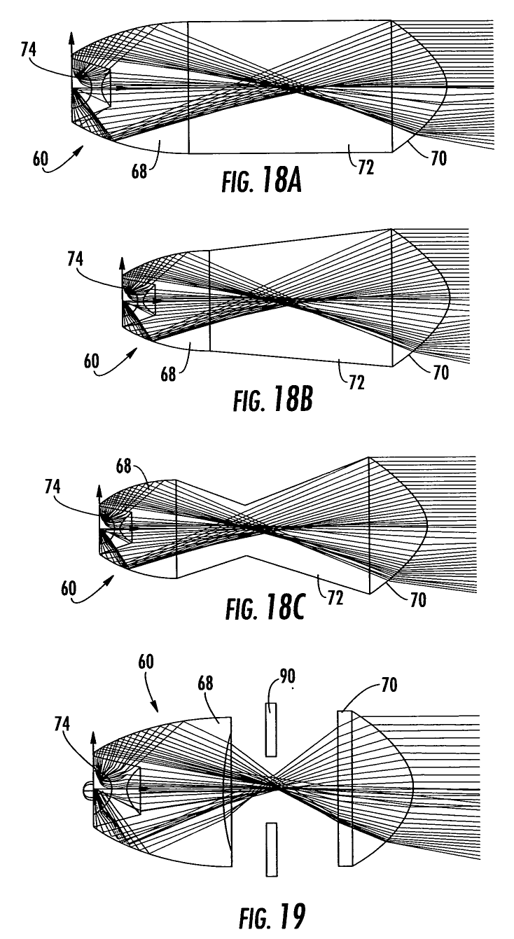

Since the transition portion 72 of the lens 60 is optically inactive, the shape can vary to suit the particular application for the lens 60. FIGS. 18a, 18b and 18c show several different shapes that the transition section 72 can be formed into without affecting the overall performance of the lens 60. FIG. 18a shows that the transition section 72 is simply a straight-sided cylinder. FIG. 18b shows the walls having a slight taper. FIG. 18c shows the center of the transition section 72 pinched at approximately the focal point 78 of the collector section 72. In this manner, the edges of the light image may be further controlled and the material required to form the lens 60 can be reduced. FIG. 19 illustrates the use of an aperture stop 90 to further control the shape of the beam image. The stop 90 may form a perfect circle to clip the edges of the beam and make a sharp near field image that is captured and transferred to the far field by the projector portion 70. As can be appreciated this aperture stop 90 could also be formed into many other shapes to create novel beam outputs such as stars, hearts, etc.

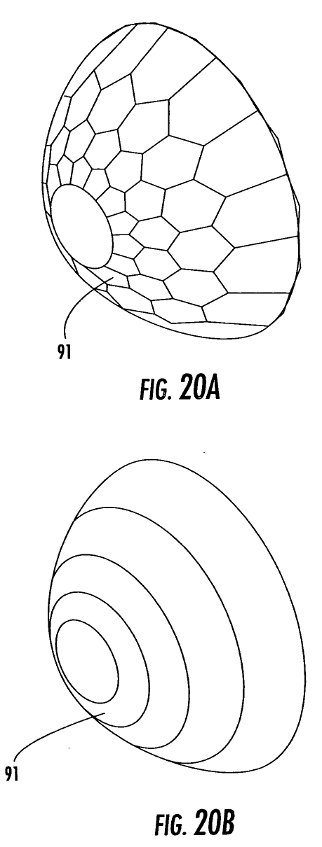

To further homogenize the beam output and create a more uniform far field image, the front face 91 of the projector section 70 may include facets. FIGS. 20a and 20b illustrate two possible facet configurations. FIG. 20a shows a honeycomb facet pattern and FIG. 20b shows a concentric circular facet pattern. As is well known in the art the facets serve to smear the light image thereby having a homogenizing effect on the overall output image that levels out beam hot spots.

FIGS. 21 and 21A illustrate a third alternate embodiment of the optical lens 360 of the present invention. This particular optical lens 360 is particularly suited for coupling the light output from the high intensity LED 12 with a light conduit 362 such as a monolithic fiber optic light pipe or a bundle that includes a plurality of optical fibers. The optical lens 360 utilizes the same collector 68 geometry as discussed above. The collector portion 68, as was discussed in detail above, serves to collect and redirect a high percentage of the light output from the LED 12 and direct it forwardly on axis to a focal point 78. A transition section 372 is provided that is shorter than the transition section 72 disclosed above. In this embodiment, the transition section 372 extends from the collector section 68 to a terminal face 374 that is positioned to fall within a focal region 375 defined by the dashed lines shown in FIG. 21. Further, the focal region 375 is positioned so that it occupies a range from partially before to partially after the point of maximum convergence of the light output from the collector 68. In other words, the focal region 375 is a region that surrounds and includes the focal length 78 of the collector section 68. While it is preferable that the terminal face 374 resides at the focal length 78 of the collector 68, the terminal face 374 may also reside anywhere within the focal region 375 and still fall within the scope of the present invention. In this manner, the terminal face 374 of the transition section 372 provides a reference point that is located at a distance from the LED light source 12, which corresponds with the overall focal length 78 of the collector section 68. In the preferred embodiment this terminal face 374 of the transition section 372 is polished although other finishes may be utilized depending on the ultimate end use of the optical lens 360. With the transition section 372 of the optical lens 360 shortened in this manner, all of the captured light output from the LED 12 is redirected to a small concentric beam image that resides at a centrally located point on the terminal face 374 of the transition section 372. This tightly focused, highly homogenized beam pattern found on the terminal face 374 of the transition section 372 is perfectly suited for discharge into the end of an optical conduit 362 such as a fiber optic light pipe. Similarly, a bundle of fibers can be positioned as shown in FIG. 21 thereby distributing the collected light output into a plurality of optical fibers. The light conduit 362 in this case can be butt coupled with the optical lens 360 using an optical adhesive. Similarly, additional structure, such as a housing 361, may be provided around the light conduit 362 and the lens 360 to maintain their relative positioning to one another. The housing 361 also serves to protect the optical lens 360 and terminal ends of the light conduit 362 whils also assisting in maintaining their relative alignment. In this manner, the optical lens 360 of the present invention provides a highly efficient means for coupling a high percentage of the LED 12 light output into a fiber optic conduit 362.

It is particularly advantageous to use the optical lens 360 of the present invention for coupling the LED 12 to an optical conduit 362 because rather than simply collimating light output as was done using prior art TIR lenses, the optical lens 360 of the present invention converges the light to a focal point 78. It is this convergence feature that allows the output light to be directed into an optical conduit 362 at a normal angle that is less than the critical angle of the optical conduit 362, thereby allowing the optical conduit 362 to transmit the coupled light output. Using this particular arrangement 90 percent of the luminous flux output from the LED 12 exits the output face 374 within an aperture angle of 27 degrees. Further, the overall size of the beam image at the focal point 78 as it exits the output face 374 of the transition portion 372 can easily be adjusted by utilizing spacers 376 that are positioned between the mounting base 20 of the LED 12 and the collector portion 68 of the optical lens 360 without impacting the angular distribution of 27 degrees. Spacers 376 of varying size can be positioned between the LED 12 and the collector portion 68 to adjust the relationship between the actual light output from the LED 12 and the collector portion 68 thereby tuning the manner in which the optical lens 360 handles and redirects the light output. By adjusting the relative spacing of the LED 12 and the collector portion 68, the size of the beam image and normal angle of the light output at the focal point 78 of the collector portion 68 can be adjusted to suit the overall diameter of the particular optical conduit 362 with which the optical lens 360 will be coupled.

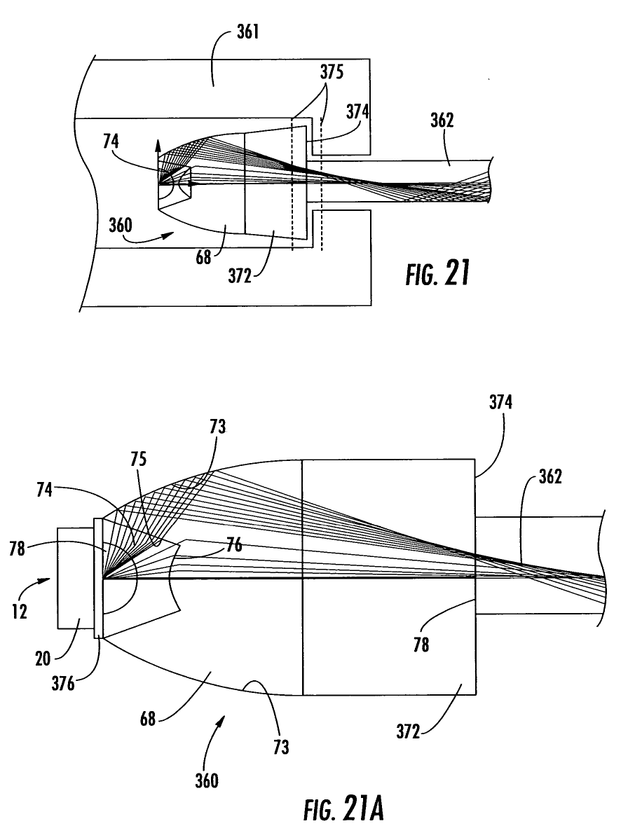

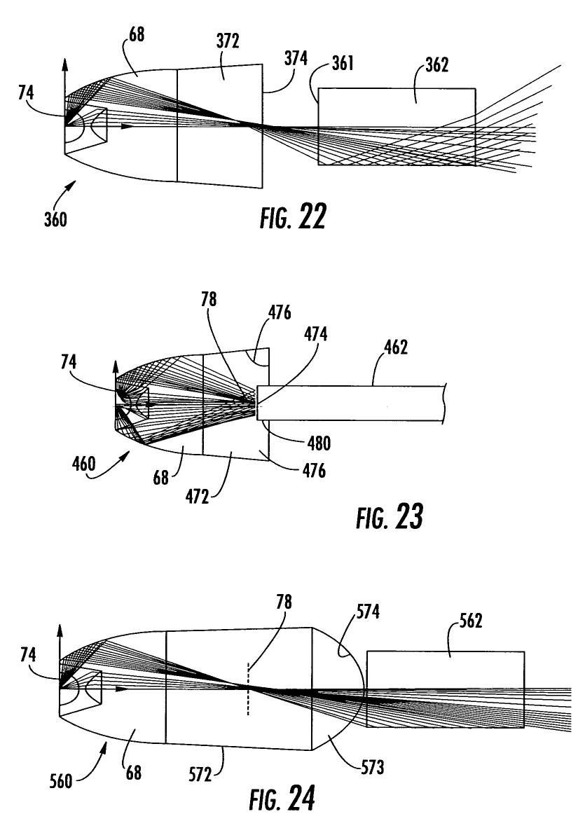

FIG. 22 illustrates a particular configuration wherein the light conduit 362 is positioned in spaced relation to the output face 374 of the optical lens 360. This configuration is particularly applicable when the light conduit 362 is formed as a large fiber bundle including a plurality of grouped fibers. By slightly shifting the fiber bundle light conduit 362 away from the output face 374 of the optical lens 360, the size of the output beam as it enters the input face 361 of the fiber bundle light conduit 362 is larger, thereby illuminating the entire face of the light conduit 362. In this manner, by illuminating the entire input face 361, effectively each of the individual fibers within the fiber bundle light conduit 362 is illuminated in contrast to smaller beam patterns wherein peripheral fibers within the fiber bundle light conduit 362 may remain dark.

Turning to FIG. 23, a fourth alternate embodiment of the optical lens 460 of the present invention is shown and illustrated. The optical lens 460 shown in this embodiment is truncated as provided in FIG. 23 above. The transition section 472 has an output face 474 that corresponds to the focal length 78 of the collector portion 68. In addition, the optical lens 460 includes structure that serves as an alignment guide and retention means for positioning an optical conduit 462 to be coupled with the optical lens 460. This retention structure 476 may be formed integrally with the body of the optical lens 460. In the simplest form, the lens 460 is molded to include the necessary retention structure 476, thereby forming a centrally located hole 480 that extends to the output face 474 of the transition portion 472. Optionally, this retention structure 476 may be added onto the lens 460 or be a portion of a housing that serves to enclose the lens 460 which includes a port for receiving and retaining the optical conduit 462.

Turning now to FIG. 24, a fifth embodiment of the optical lens 560 of the present invention is shown. In this embodiment of the optical lens 560, the projector portion 573 is reintroduced in front of the transition section 572. The output face 574 accordingly includes a convex shape that serves to further collimate the beam as it is refracted when passing through the output face 574. The purpose of reintroducing the projector 573 is to maintain the total amount of flux collected and directed from the LED 12 while dramatically reducing the angular distribution of the beam as it is transferred to the light conduit 562. In this example, 90 percent of the luminous flux output exits the output face 574 at a distribution angle of within 13 degrees. By lowering the angular distribution of the flux in this manner, the flux can propagate over longer transmission distances after entering the light conduit 562.

It can therefore be seen that the present invention provides a compact lighting assembly 1 that provides an integrated heat sink LED sub-assembly 10 coupled with a lens 60 configuration that includes integral reflector 68 and projector 70 components that cooperate in a highly efficient manner to gather the diffuse light output from a high intensity light source 12. Further, the present invention operates in an efficient manner to collimate and homogenize the light output thereby forming a highly desirable uniform and circular far field beam image while dissipating waste heat from a high intensity LED source 12 that has been previously unknown in the art. Finally, the present invention provides a lens that serves as a highly efficient coupling device to transfer light from a high output LED into a light conduit. For these reasons, the instant invention is believed to represent a significant advancement in the art, which has substantial commercial merit.

While there is shown and described herein certain specific structure embodying the invention, it will be manifest to those skilled in the art that various modifications and rearrangements of the parts may be made without departing from the spirit and scope of the underlying inventive concept and that the same is not limited to the particular forms herein shown and described except insofar as indicated by the scope of the appended claims.

1. A lens for coupling light output from a light source with an input end of an optical conduit, said lens comprising:
a total internal reflection collector portion at a first end thereof, said collector having a focal region; and
a transition portion extending from said collector portion to an output face said output face positioned within said focal region of said collector portion.

2. The lens of claim 1, further comprising:
a light source positioned adjacent said collector portion of said lens; and
a light conduit having a first end positioned adjacent said output face, wherein light output from said light source is directed into said collector portion of said lens and discharged into said first end of said light conduit.

3. The lens of claim 2, said lens further comprising:
means for receiving and retaining said light conduit in a fixed position adjacent said output face.

4. The lens of claim 3, wherein said means for receiving and retaining said light conduit is integrally formed with said lens.

5. The lens of claim 3, wherein said means for receiving and retaining said light conduit is a housing configured to receive said lens and said first end of said optical conduit therein.

6. The lens of claim 2, wherein said light source is a light emitting diode.

7. The lens of claim 2, wherein said light conduit is selected from the group consisting of: optical rods, optical fibers and a bundle containing a plurality of optical fibers.

8. The lens of claim 2, further comprising:
at least one spacer between said light source and said collector portion to adjust the relative spacing between said light source and said collector.

9. The lens of claim 1, said total internal reflection collector portion including a focal length positioned within said focal region, said output face of said transition portion positioned at said focal length.

10. The lens of claim 1, wherein said lens is glass.

11. The lens of claim 1, wherein said lens is an optical grade polymer.

12. The lens of claim 1, said collector portion comprising:
a rear surface;
an outer side wall; and
a cavity extending into said collector portion from said rear surface, said cavity having an inner side wall and a front wall, said light source disposed substantially within said cavity.

13. The lens of claim 12, wherein said outer sidewalls are outwardly tapered between said rear surface and said transition section.

14. The lens of claim 12, wherein said outer sidewalls are hemispherical between said rear surface and said transition section.

15. The lens of claim 12, wherein said outer sidewalls are elliptically curved between said rear surface and said transition section.

16. The lens of claim 12, wherein said front wall is convexly curved rewardly toward said light source.

17. A lens for coupling light output from a light source with an input end of an optical conduit, said lens comprising:
a total internal reflection collector portion at a first end thereof, said collector having a focal region;
a transition portion extending from said collector portion to an output face said output face positioned within said focal region of said collector portion, said output face having a central region and a peripheral region concentrically located about said central region; and
a retention structure extending from said peripheral region of said output face, said retention structure capable of receiving and retaining said optical conduit in a position adjacent said central region of said output face.

18. The lens of claim 17, further comprising:
a light source positioned adjacent said collector portion of said lens; and
a light conduit having a first end positioned adjacent said output face, wherein light output from said light source is directed into said collector portion of said lens and discharged into said first end of said light conduit.

19. The lens of claim 18, wherein said light source is a light emitting diode.

20. The lens of claim 18, wherein said light conduit is selected from the group consisting of: optical rods, optical fibers and a bundle containing a plurality of optical fibers.

21. The lens of claim 18, further comprising:
at least one spacer between said light source and said collector portion to adjust the relative spacing between said light source and said collector.

22. The lens of claim 17, said total internal reflection collector portion including a focal length positioned within said focal region, said output face of said transition portion positioned at said focal length.

23. The lens of claim 17, said collector portion comprising:
a rear surface;
an outer side wall; and
a cavity extending into said collector portion from said rear surface, said cavity having an inner side wall and a front wall, said light source disposed substantially within said cavity.

24. The lens of claim 23, wherein said outer sidewalls are outwardly tapered between said rear surface and said transition section.

25. The lens of claim 23, wherein said outer sidewalls are hemispherical between said rear surface and said transition section.

26. The lens of claim 23, wherein said outer sidewalls are elliptically curved between said rear surface and said transition section.

27. The lens of claim 23, wherein said front wall is convexly curved rewardly toward said light source.

28. A lighting assembly comprising:
a lens for directing light output forwardly along an optical axis, wherein said lens includes:
a total internal reflection collector portion at a first end thereof, said collector having a focal region, said collector having a cavity therein, and
a transition portion extending from said collector portion to an output face said output face positioned within said focal region of said collector portion;
a light source disposed substantially within said cavity, said light source having a central axis, said light source configured to emit a first portion of light output substantially along said central axis and a second portion of light output substantially divergent from said central axis; and
a light conduit having a first end positioned adjacent said output face,
wherein said collector portion collimates and homogenizes said first and second portions of light output to form a circular, uniform discharge beam at said output face, said beam being transferred into said first end of said light conduit.

29. An assembly for coupling light output from a light source with an input end of an optical conduit, said assembly comprising:
a lens including:
a total internal reflection collector portion at a first end thereof, said collector having a focal length,
a projector portion at a second end opposite said first end, and
a transition portion extending between said collector portion and said projector portion, said lens having an overall length wherein said overall length is longer than the focal length of said collector portion;
a light source positioned adjacent said collector portion of said lens; and
a light conduit having a first end positioned adjacent said output face, wherein light output from said light source is directed into said collector portion of said lens, collimated by said projector portion of said lens and discharged into said first end of said light conduit.

30. The assembly of claim 29, said lens further comprising:
means for receiving and retaining said light conduit in a fixed position adjacent said output face.

31. The assembly of claim 30, wherein said means for receiving and retaining said light conduit is a housing configured to receive said lens, said light source and said first end of said optical conduit therein.

32. The assembly of claim 29, wherein said light source is a light emitting diode.

33. The assembly of claim 29, wherein said light conduit is selected from the group consisting of: optical rods, optical fibers and a bundle containing a plurality of optical fibers.
